(19) United States
(12) Patent Application Publication
(10) Pub. No.: US 2012/0249251 A1
(43) Pub. Date: Oct. 4, 2012

(54) GENERATION OF BEZIER CURVE AS CONTROL SIGNAL FOR OSCILLATING CIRCUIT

(75) Inventors: Takayuki NAKAMURA, Tokyo (JP); Minoru SAKAI, Tokyo (JP)

(73) Assignee: MITSUMI ELECTRIC CO.,LTD

(21) Appl. No.: 13/411,997

(22) Filed: Mar. 5, 2012

(30) Foreign Application Priority Data
Mar. 31, 2011 (JP) 2011-080172

(51) Int. Cl. H03K 3/02

(52) U.S. Cl. 331/66

(57) ABSTRACT

A function generating circuit for producing a control signal for an oscillating circuit that vibrates a crystal unit includes a temperature detecting circuit to detect an ambient temperature, and a Bezier-curve generating circuit to produce a Bezier curve as the control signal in response to the ambient temperature detected by the temperature detecting circuit.

### BACKGROUND OF THE INVENTION

1. Field of the Invention

The disclosures herein relate to a function generating circuit that produces a control signal for an oscillating circuit that vibrates a crystal unit.

2. Description of the Related Art

Crystal oscillators are known to have highly-stable frequency. Crystal oscillators have frequency-temperature characteristics that are approximated by a cubic function with respect to ambient temperature T, as illustrated by a solid line in FIG. 1. A temperature-compensated crystal oscillator (TCXO) 50 illustrated in FIG. 2 is provided with a temperature compensation circuit 20, which serves as a function generating circuit that generates a control voltage Vc, based on ambient temperature T detected by a temperature detecting circuit 2, for controlling an oscillating circuit 30 that vibrates a crystal unit 35. The temperature compensation circuit 20 applies the control voltage Vc to variable-capacitance devices 31 and 32 of the oscillating circuit 30, thereby compensating for variation of the oscillating frequency (i.e., TCXO output) output from the OSCOUT terminal caused by the frequency-temperature characteristics (see FIG. 1).

In general, the control voltage Vc generated by the temperature compensation circuit 20 is obtained by adding together voltages generated by a cubic-component generating circuit 6, a linear-component generating circuit 5, and a zero-order-component generating circuit 4, respectively. The control voltage Vc is defined by a temperature compensating curve expressed by a cubic function as shown below in an expression (1).

Vc=α(T−T0)³+β(T−T0)+γ (1)

Here, α is a coefficient for the third-order term, and β is a coefficient for the first-order term, with γ being a coefficient for the zero-order term. T0 is a temperature at the inflection point of the cubic curve (i.e., reference center temperature). A T0-adjustment circuit 3 adjusts T0. Specifically, the T0-adjustment circuit 3 adjusts T0 appearing in the expression (1) such that T0 coincides with the inflection-point temperature that is determined by the temperature characteristics of the crystal oscillator including a crystal unit 35.

Patent Documents 1, 2, and 3 are examples of related-art documents that disclose function generating circuits.

There is a limit to the accuracy with which a cubic function can approximate the frequency-temperature characteristics of a crystal oscillator. Especially in a higher-temperature range (e.g., 80 degrees Celsius or higher) and a lower-temperature range (e.g., −30 degrees Celsius or lower), it is difficult for the cubic function of the expression (1), as illustrated in FIG. 3 and FIG. 4, to provide for the control signal of the oscillating circuit for vibrating a crystal unit to approximate a desired temperature compensating curve that can accurately compensate for the vibration of the TCXO output, which is caused by the frequency-temperature characteristics of the crystal oscillator.

Accordingly, it is preferable to provide a function generating circuit, a control signal generating method, and a curve fitting method that can provide for a control signal of an oscillating circuit for vibrating a crystal unit to easily approximate a desired temperature compensating curve.

### [Patent Document 1] Japanese Patent No. 4070139

### [Patent Document 2] Japanese Patent Application Publication No. 2007-325033

### [Patent Document 3] Japanese Patent Application Publication No. 8-116214

### SUMMARY OF THE INVENTION

It is a general object of the present invention to provide a function generating circuit, a control signal generating method, and a curve-fitting method that substantially obviates one or more problems caused by the limitations and disadvantages of the related art.

According to an embodiment, a function generating circuit for producing a control signal for an oscillating circuit that vibrates a crystal unit includes a temperature detecting circuit to detect an ambient temperature, and a Bezier-curve generating circuit to produce a Bezier curve as the control signal in response to the ambient temperature detected by the temperature detecting circuit.

According to an embodiment, a control signal generating method includes generating, in response to a detected ambient temperature, a Bezier curve as a control signal for an oscillating circuit that vibrates a crystal unit.

According to an embodiment, a curve-fitting method includes utilizing a Bezier curve to approximate, in response to a detected ambient temperature, a control signal for an oscillating circuit that vibrates a crystal unit.

According to at least one embodiment, a control signal for an oscillating circuit that vibrates a crystal unit can easily approximate a desired temperature compensating curve.

### BRIEF DESCRIPTION OF THE DRAWINGS

Other objects and further features of the present invention will be apparent from the following detailed description when read in conjunction with the accompanying drawings, in which:

FIG. 1 is a drawing illustrating a frequency error (Δf/f0) of a natural resonance frequency associated with temperature changes when the natural resonance frequency is f0 at the inflection-point temperature of a cubic curve;

FIG. 2 is a block diagram illustrating a related-art TCXO;

FIG. 3 is a drawing illustrating the temperature characteristics of frequency error;

FIG. 4 is a drawing illustrating the temperature characteristics of frequency error;

FIG. 5 is a block diagram illustrating a TCXO according to an embodiment;

FIG. 6 is a drawing for explaining a quadratic Bezier curve;

FIG. 7 is a block diagram of a quadratic-Bezier-curve circuit;

FIG. 8 is a block diagram of another quadratic-Bezier-curve circuit;

FIG. 9 is a block diagram of a square-root circuit;

FIG. 10 is a block diagram illustrating an example of a temperature compensating circuit using a quadratic-Bezier-curve circuit; and

FIG. 11 is a drawing illustrating the temperature range of a control voltage that is divided into two ranges each including one extremal point.

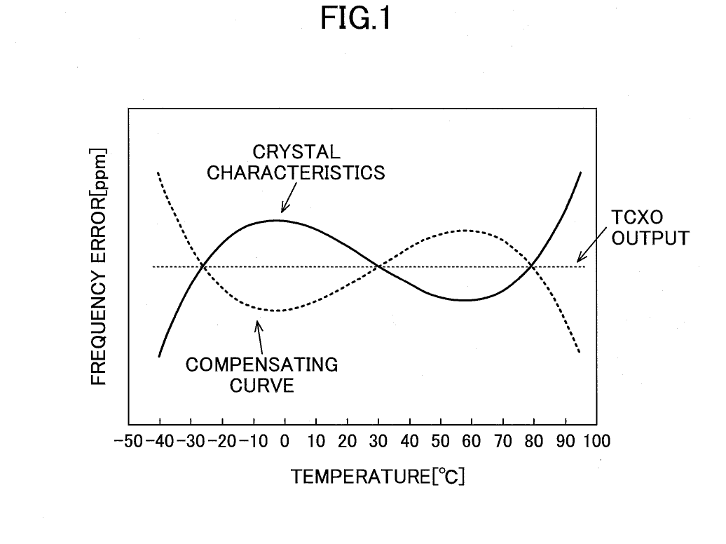

### DESCRIPTION OF THE PREFERRED EMBODIMENTS

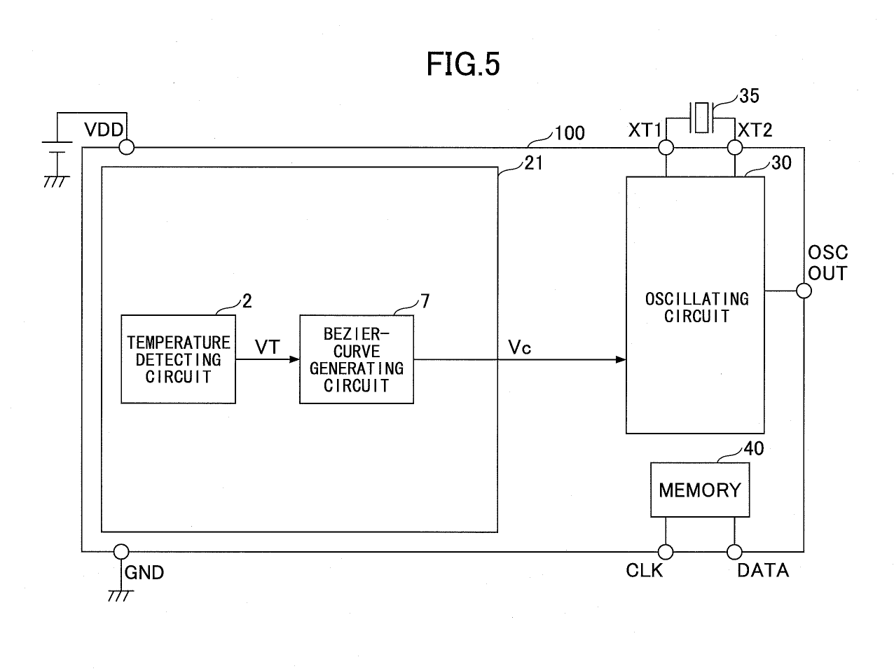

In the following, embodiments will be described with reference to the accompanying drawings. FIG. 5 is a block diagram illustrating a TCXO 100 according to an embodiment. The TCXO 100 includes a semiconductor integrated circuit (IC).

The TCXO 100 includes a temperature compensating circuit 21, the oscillating circuit 30 for vibrating the AT-cut crystal unit 35, and a memory 40.

The temperature compensating circuit 21 is a function generating circuit that produces the control voltage Vc for the oscillating circuit 30 in response to the ambient temperature T.

The oscillating circuit 30 uses the crystal unit 35 as a resonator to generate an oscillating output at the OSCOUT terminal having constant oscillating frequency. The crystal unit 35 connected to the oscillating circuit 30 is externally attached to an input-side terminal XT1 and an output-side terminal XT2 of the TCXO 100.

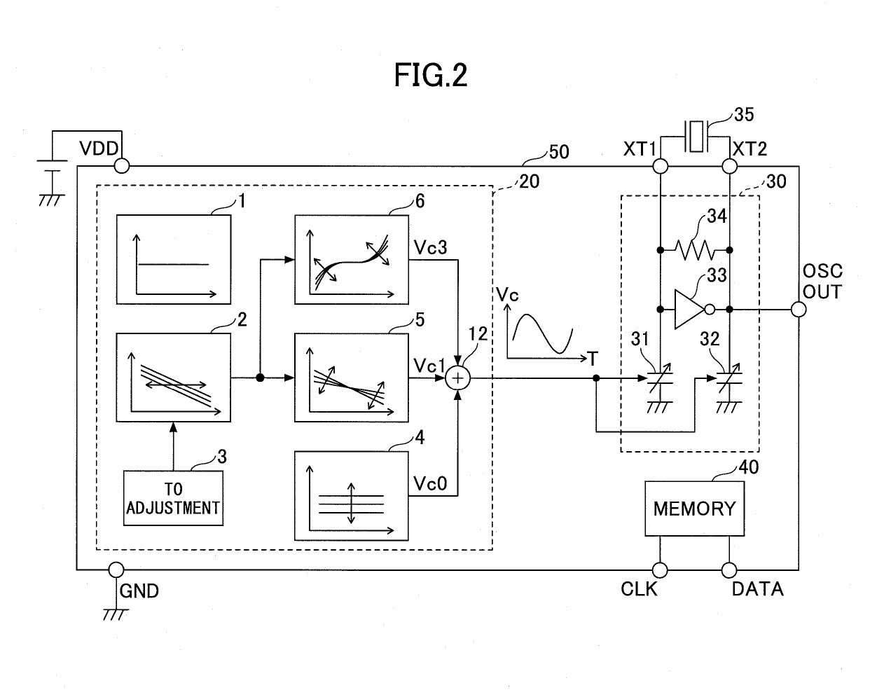

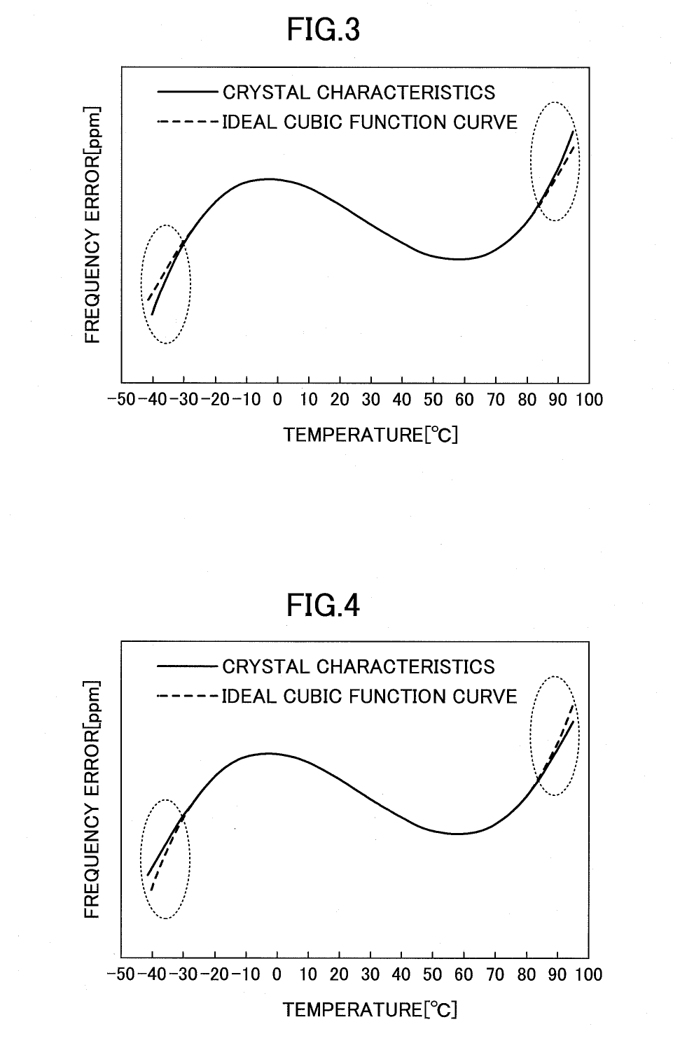

As illustrated in FIG. 2, for example, the oscillating circuit 30 includes a CMOS inverter 33 connected in parallel to the crystal unit 35 between the input terminal and the output terminal, a variable-capacitance device 31 connected between the input of the CMOS inverter 33 and the ground, a variable-capacitance device 32 connected between the output of the CMOS inverter 33 and the ground, and a feedback resistor 34 connected in parallel to the CMOS inverter 33 between the input and output thereof. A variable-capacitance diode (i.e., varicap) may be an example of the variable-capacitance device. The oscillating circuit 30 produces at the OSCOUT terminal an oscillating output having constant oscillating frequency in response to the control voltage Vc applied between two ends of each of the variable-capacitance devices. The oscillating circuit 30 is not limited to this configuration.

The memory 40 in FIG. 5 is a device for storing data used by a Bezier-curve generating circuit 7 of the temperature compensating circuit 21 to generate a Bezier curve (e.g., data indicative of coordinates of control points of the Bezier curve or constants a to e, as will be described later). The data stored in the memory 40 can be rewritten from outside the TCXO 100 via a CLK terminal and a DATA terminal. The memory 40 stores adjusted data tailored for each product prior to the shipment of the product.

The temperature compensating circuit 21 serves as a function generating circuit that is provided with a temperature detecting circuit 2 and the Bezier-curve generating circuit 7.

The temperature detecting circuit 2 detects as the ambient temperature T the temperature of the TCXO 100 inclusive of the oscillating circuit and/or the temperature of the crystal unit 35. The temperature detecting circuit 2 produces a voltage responsive to the detected ambient temperature T as a detection voltage VT indicative of the ambient temperature T by use of linear temperature characteristics (e.g., negative linear temperature characteristics). The temperature detecting circuit 2 may produce the detection voltage VT indicative of the ambient temperature T that is a voltage monotonically decreasing with an increase of the ambient temperature T, i.e., a voltage exhibiting a change with negative linear temperature characteristics.

The Bezier-curve generating circuit 7 generates the control voltage Vc having a Bezier curve in response to the ambient temperature T detected by the temperature detecting circuit 2.

The Bezier curve is a m−1-th-order curve that is drawn by use of m control points. The Bezier curve is expressed as follows by use of control points B₀, B₁, . . . , Bₘ₋₁.

$$P ( t ) = {\sum }_{i = 0}^{m - 1} {B}_{i} {J}_{{( m - 1 )}_{i}} ( t ) \qquad ( 2 )$$

Here, J₍ₘ₋₁₎ᵢ(t) is a blending function of a Bernstein basis function. In the expression (2), a Bezier curve having B₀ and Bₘ₋₁ as two opposite ends is generated by changing parameter “t” from 0 to 1.

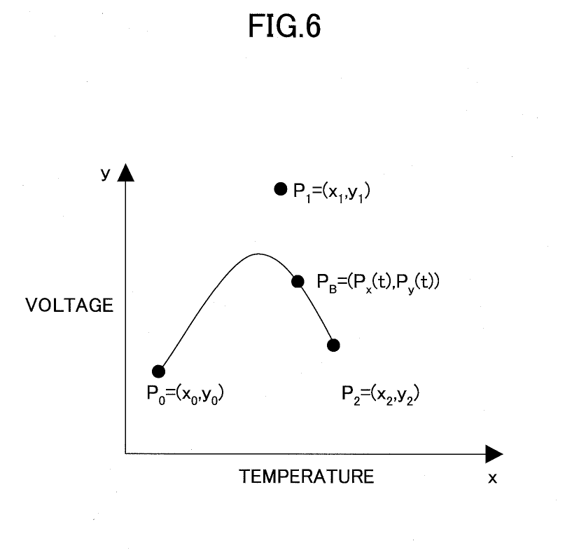

In the following, a description will be given of a quadratic Bezier curve for which m is equal to 3 and control points P₀=(x₀, y₀), P₁(x₁, y₁), and P₂=(x₂, y₂) are provided, by referring to FIG. 6. Here, the condition of x₀≦x₁≦x₂ is taken as granted.

Any point P_{B}(t)=(Pₓ(t), P_{y} (t)) on the quadratic Bezier curve is expressed by functions of t as shown in expressions (3) and (4) (0≦t≦1).

Pₓ(t)=(1−t)²x₀+2t(1−t)x₁+t²x₂ (3)

P_{y}(t)=(1−t)²y₀+2t(1−t)y₁+t²y₂ (4)

P_{B}(t) becomes P₀ when t=0, and becomes P₂ when t=1. A change in the coordinates of the control point P₁ adjusts the degree of the curvature of the Bezier curve. The expression (3), when sorted by t, becomes a quadratic equation (5) with respect to t. Since the condition of 0≦t≦1 is satisfied, t is expressed by equation (6) by use of Pₓ(t).

$$\begin{matrix}( {x}_{0} - 2 {x}_{1} + {x}_{2} ) {t}^{2} + 2 ( {x}_{1} - {x}_{0} ) t + {x}_{0} - {P}_{x} ( t ) = 0 & ( 5 ) \\ t = \frac{\sqrt{{x}_{j}^{2} - {x}_{0} {x}_{2} + ( {x}_{0} - 2 {x}_{1} + {x}_{2} ) {P}_{x} ( t )} - ( {x}_{1} - {x}_{0} )}{{x}_{0} - 2 {x}_{1} + {x}_{2}} & ( 6 )\end{matrix}$$

An equation (7) is obtained by incorporating the equation (6) into the expression (4). Namely, P_{y}(t) becomes a function of Pₓ(t). P_{y}(t) corresponds to the control voltage Vc. Pₓ(t) corresponds to the ambient temperature T.

$$\begin{matrix}{P}_{y} ( t ) = a + b \sqrt{c + d {P}_{x} ( t )} + {eP}_{x} ( t ) & ( 7 ) \\ a = \frac{{y}_{0} [ {( {x}_{1} - {x}_{2} )}^{2} + {x}_{1}^{2} - {x}_{0} {x}_{2} ] + {y}_{1} [ - 2 {{x}_{1} ( {x}_{0} + {x}_{2} )}^{2} + 4 {x}_{0} {x}_{2} ] + {y}_{2} [ {( {x}_{1} - {x}_{0} )}^{2} + {x}_{1}^{2} - {x}_{0} {x}_{2} ]}{{( {x}_{0} - 2 {x}_{1} + {x}_{2} )}^{2}} & ( 8 ) \\ b = \frac{2 [ {y}_{0} ( {x}_{1} - {x}_{2} ) + {y}_{1} ( {x}_{2} - {x}_{0} ) + {y}_{2} ( {x}_{0} - {x}_{1} ) ]}{{( {x}_{0} - 2 {x}_{1} + {x}_{2} )}^{2}} & ( 9 ) \\ c = {x}_{1}^{2} - {x}_{0} {x}_{2} & ( 10 ) \\ d = {x}_{0} - 2 {x}_{1} + {x}_{2} & ( 11 ) \\ e = \frac{{y}_{0} - 2 {y}_{1} + {y}_{2}}{{x}_{0} - 2 {x}_{1} + {x}_{2}} & ( 12 )\end{matrix}$$

Coefficients a, b, c, d, and e of the equation (7) are determined by the control points P₀, P₁, and P₂ as shown in expressions (8) through (12), and can thus be readily obtained from the coordinates of these three points.

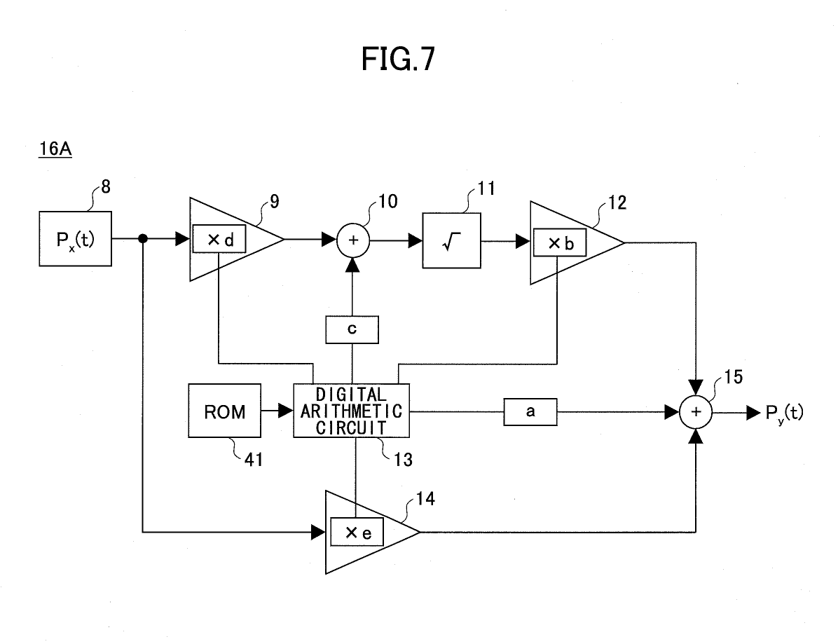

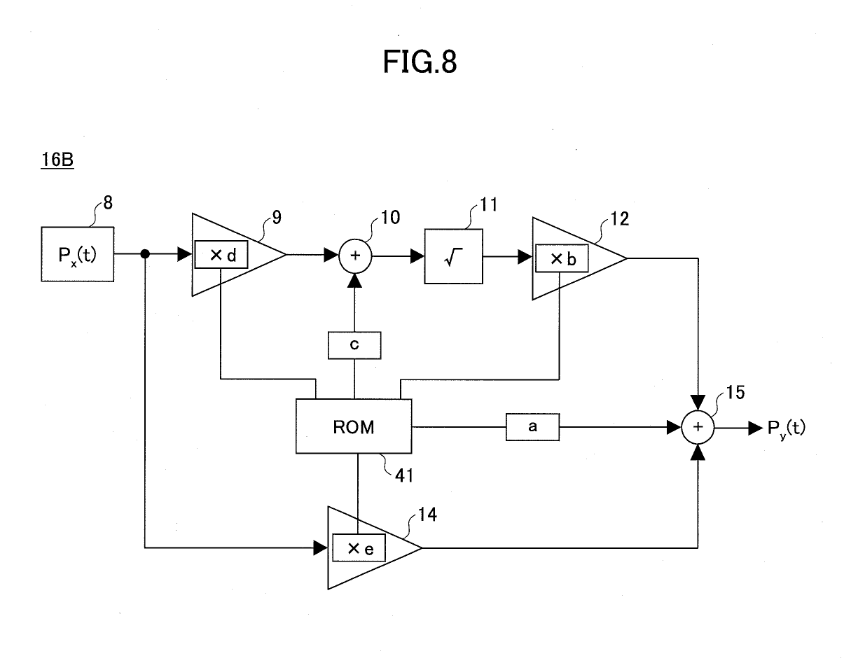

FIG. 7 and FIG. 8 are block diagrams illustrating examples of circuits for generating a quadratic Bezier curve based on the equation (7). The quadratic-Bezier-curve circuit illustrated in FIG. 7 and FIG. 8 includes a control signal generating circuit 8 for producing P_{X}(t) according to the expression (3), a first multiplier circuit 9 for producing a value obtained by multiplying P_{X}(t) by constant d, a first adder circuit 10 for producing a value obtained by adding constant c to the product produced by the first multiplier circuit 9, a square-root circuit 11 for producing a square root of the sum produced by the first adder circuit 10, a second multiplier circuit 12 for producing a value obtained by multiplying the output of the square-root circuit 11 by constant b, a third multiplier circuit 14 for producing a value obtained by multiplying P_{X}(t) by constant e, and a second adder circuit 15 for producing P_{y}(t) obtained by adding together the output of the second multiplier circuit 12, the output of the third multiplier circuit 14, and constant a.

A quadratic-Bezier-curve circuit 16A that is a first circuit example illustrated in FIG. 7 includes a digital arithmetic circuit 13 for calculating constants a, b, c, d, and e according to the expressions (8) through (12) based on the coordinate data of the three points P₀=(x₀, y₀), P₁=(x₁, y₁), and P₂=(x₂, y₂), which are stored in advance in a ROM 41 of the memory 40 (see FIG. 5). The quadratic-Bezier-curve circuit 16A calculates P_{y}(t) according to the expression (7) by use of constants a, b, c, d, and e calculated by the digital arithmetic circuit 13. A quadratic-Bezier-curve circuit 16B that is a second circuit example illustrated in FIG. 8 includes the ROM 41 that stores constants a, b, c, d, and e, which are calculated in advance in accordance with the expressions (8) through (12). The quadratic-Bezier-curve circuit 16B calculates P_{y}(t) according to the expression (7) by use of constants a, b, c, d, and e retrieved from the ROM 41.

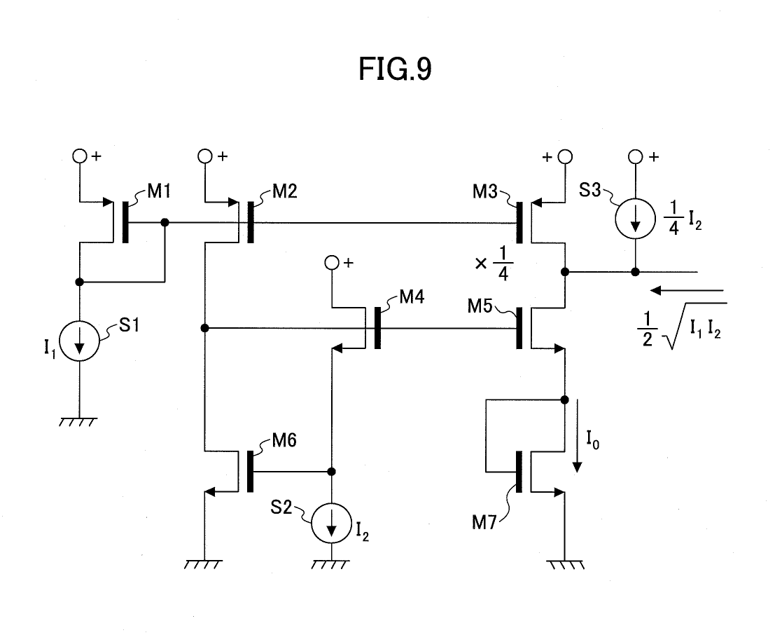

The adder circuits 10 and 15, the multiplier circuits 9, 12, and 14, and the square-root circuit 11 illustrated in FIG. 7 and FIG. 8 may be implemented as analog circuits. Specifically, the adder circuits 10 and 15 as well as the multiplier circuits 9, 12, and 14 may be implemented by use of operational amplifiers. The square-root circuit 11 may be implemented as illustrated in FIG. 9, which shows a circuit using the translinear principle. The circuit illustrated in FIG. 9 includes PMOS transistors M1 through M3, NMOS transistors M4 through M7, and current sources S1 through S3. The square-root circuit 11 is well known, and is not limited to the configuration illustrated in FIG. 9.

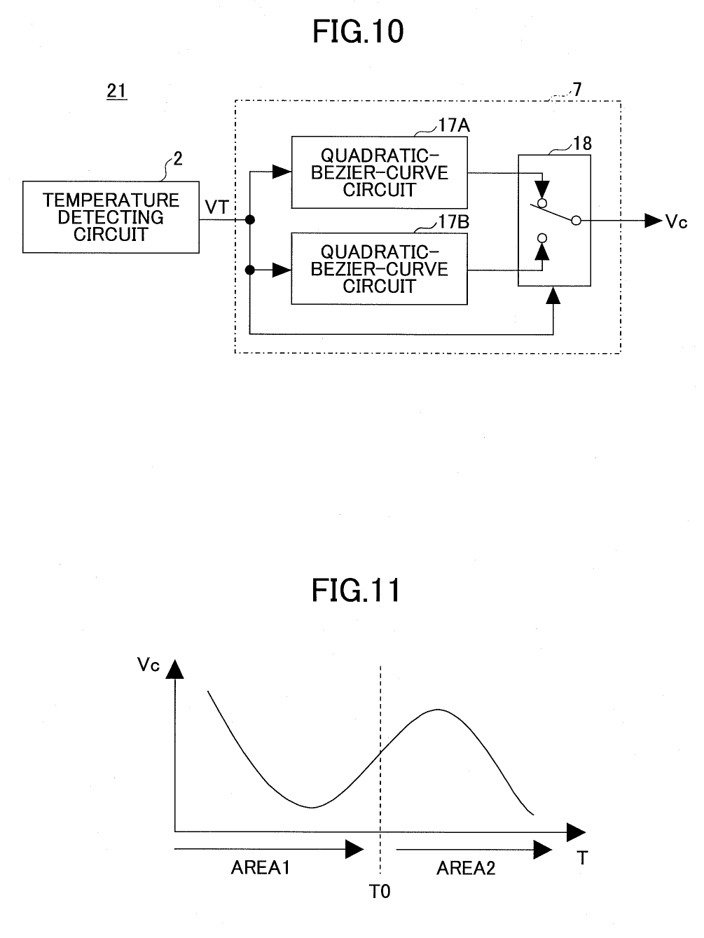

FIG. 10 is a block diagram illustrating an example of the temperature compensating circuit 21 using a quadratic-Bezier-curve circuit. The Bezier-curve generating circuit 7 includes a switch 18, which serves to switch Bezier-curve control points in response to the detection voltage VT indicative of the ambient temperature T detected by the temperature detecting circuit 2. The switch 18 selects one of the plurality of quadratic-Bezier-curve generating units for generating the control voltage Vc in response to the detection voltage VT indicative of the ambient temperature T detected by the temperature detecting circuit 2. The Bezier-curve generating circuit 7 includes two quadratic-Bezier-curve circuits 17A and 17B serving as quadratic-Bezier-curve generating units, which have respective different temperature ranges for which a Bezier curve is generated. As illustrated in FIG. 11, the temperature characteristics of the generated control voltage Vc have two extremal points corresponding to the frequency-temperature characteristics of the crystal oscillator. In consideration of this, the quadratic-Bezier-curve circuit 17A illustrated in FIG. 10 generates the control voltage Vc in a temperature range lower than the inflection-point temperature T0, and the quadratic-Bezier-curve circuit 17B generates the control voltage Vc in a temperature range higher than the inflection-point temperature T0. Curve-fitting of the control voltage Vc to a desired temperature compensating curve is performed by adjusting the coordinate data of the control points P₀, P₁, and P₂ in each temperature range.

The Bezier-curve generating circuit 7 operates the switch 18 in response to the detection voltage VT indicative of the ambient temperature T detected by the temperature detecting circuit 2, thereby selecting either one of the quadratic-Bezier-curve circuits 17A and 17B as the circuit for generating the control voltage Vc at the detected ambient temperature T.

Alternatively, the switch 18 serving as a switching unit for selecting the control points of a Bezier curve may switch the definition data of a Bezier curve retrieved from the ROM 41 of the memory 40 in response to the detection voltage VT indicative of the ambient temperature T detected by the temperature detecting circuit 2. The definition data of a Bezier curve includes the coordinate data of each control point P or the constants a, b, c, d, and e previously described, for example. The definition data are stored in the memory on a temperature-range-specific basis. The Bezier-curve generating circuit 7 uses the definition data of a Bezier curve of a temperature range corresponding to the detected ambient temperature T for a quadratic-Bezier-curve circuit illustrated in FIG. 7 or 8. With this configuration, circuit size can be reduced, compared with a case in which plural Bezier-curve circuits are provided.

According to the embodiments described heretofore, the control voltage Vc can easily approximate a desired temperature compensating curve that can accurately compensate for variation in the TCXO output caused by the frequency-temperature characteristics of a crystal oscillator. Namely, the Bezier-curve generating circuit 7 sets control points of a Bezier curve at the start point and end point of a desired temperature compensating curve, and adjusts the coordinate data of control points situated between the start point and the end point. In this manner, the Bezier-curve generating circuit 7 can generate the control voltage Vc that is curve-fitted accurately to the desired temperature compensating curve.

Accordingly, the temperature compensating circuit 21 using the Bezier-curve generating circuit can fit the control voltage Vc flexibly to the desired temperature compensating curve in a broadened temperature range even when the temperature compensation range of the TCXO is broadened to cover a temperature range lower than −30 degrees Celsius and a temperature range higher than 80 degrees Celsius.

There is no need to provide the temperature compensating circuit with a higher-order component generating circuit for generating fourth-or-higher order components in order to accurately compensate in the broadened temperature range. Circuit size can thus be reduced.

Further, the equation (7) does not include higher-order terms higher than or equal to the second order. With respect to the square-root term, also, noise included in Pₓ(t) is suppressed to the square root thereof. This arrangement can thus provide a low-noise temperature compensation circuit.

Further, the present invention is not limited to these embodiments, but various variations and modifications may be made without departing from the scope of the present invention.

For example, the equation (7) may be modified into an equation (13), which does not include the first-order term, thereby providing a circuit with yet lower noise.

$${P}_{y} ( t ) = a - \frac{ce}{d} + ( b + \frac{e}{d} \sqrt{c + {dP}_{x} ( t )} ) \times \sqrt{c + {dP}_{x} ( t )} \qquad ( 13 )$$

Moreover, the term that includes the square root in the equation (7) is modified into an expression (14).

$$b \sqrt{c + {dP}_{x} ( t )} = kb \sqrt{\frac{c + {dP}_{x} ( t )}{{k}^{2}}} = {b}^{′} \sqrt{{c}^{′} + {d}^{′} {P}_{x} ( t )} \\ {b}^{′} = kb \\ {c}^{′} = \frac{c}{{k}^{2}} \\ {d}^{′} = \frac{d}{{k}^{2}} \qquad ( 14 )$$

In the expression (14), the value of k may be changed to adjust b′, c′, and d′. This fact reveals that gain may be distributed between b and a set of c and d. When k is set equal to 1/|b|, |b′| becomes equal to 1. In this case, the multiplier circuit 12 (i.e., amplifier for multiplication by b) can be omitted from the circuits illustrated in FIG. 7 and FIG. 8. When k is set equal to |d|^{1/2}, |d′| becomes equal to 1. In this case, thus, the multiplier circuit 9 (i.e., amplifier for multiplication by d) can be omitted from the circuits illustrated in FIG. 7 and FIG. 8.

In the case of a temperature compensation circuit using one or more quadratic-Bezier-curve circuits, an increase in the number of divided temperature ranges results in higher accuracy in the generation of the control voltage Vc.

A higher-order Bezier curve for m=4 or larger may also be implemented by representing P_{y}(t) as a function of Pₓ(t), using a memory such as a ROM or a digital arithmetic circuit for obtaining relevant constants, and performing the remaining arithmetic operations by use of analog arithmetic circuits, as was previously described. Since a higher-order Bezier curve for m=4 or larger has two or more extremal points, a temperature compensation circuit that achieves highly accurate approximation of a desired temperature compensating curve may be implemented even without dividing a temperature range in which the control voltage Vc is defined.

In the embodiments described above, the switch 18 was used as a switching unit for switching Bezier-curve control points in response to detected ambient temperature. The switch 18 may be implemented by use of hardware comprised of transistors and the like. Alternatively, the switch may be implemented as software by use of a program executed by a central processing unit (CPU).

The present application is based on Japanese priority application No. 2011-080172 filed on Mar. 31, 2011, with the Japanese Patent Office, the entire contents of which are hereby incorporated by reference.

What is claimed is:

1. A function generating circuit for producing a control signal for an oscillating circuit that vibrates a crystal unit, comprising:
a temperature detecting circuit to detect an ambient temperature; and
a Bezier-curve generating circuit to produce a Bezier curve as the control signal in response to the ambient temperature detected by the temperature detecting circuit.

2. The function generating circuit as claimed in claim 1, wherein the Bezier-curve generating circuit includes a switching unit that switches Bezier-curve control points in response to the ambient temperature detected by the temperature detecting circuit.

3. The function generating circuit as claimed in claim 2, wherein the switching unit switches Bezier-curve definition data retrieved from a memory in response to the ambient temperature detected by the temperature detecting circuit.

4. The function generating circuit as claimed in claim 2, wherein the Bezier-curve generating circuit includes plural Bezier-curve generating units, and the switching unit selects one of the Bezier-curve generating units in response to the ambient temperature detected by the temperature detecting circuit.

5. The function generating circuit as claimed in claim 1, wherein the Bezier curve is a quadratic Bezier curve.

6. The function generating circuit as claimed in claim 5, wherein the Bezier-curve generating unit includes:
a first multiplier circuit to multiply an output of a control-signal generating circuit by a first predetermined value;
a first adder circuit to add a second predetermined value to an output of the first multiplier circuit;
a square-root circuit to calculate a square root of an output of the first adder circuit;
a second multiplier circuit to multiply an output of the square-root circuit by a third predetermined value;
a third multiplier circuit to multiply the output of the control-signal generating circuit by a fourth predetermined value;
a second adder circuit to add together an output of the second multiplier circuit, an output of the third multiplier circuit, and a fifth predetermined value.

7. The function generating circuit as claimed in claim 5, wherein the Bezier curve is approximated by:
P_{y}(t)+a+b\sqrt{c+dPₓ(t)}+ePₓ(t)
wherein P_{y}(t) corresponds to the control voltage, and P_{X}(t) corresponds to the detected ambient temperature.

8. A crystal oscillator circuit, comprising:
the function generating circuit of claim 1; and
the oscillating circuit.

9. A crystal oscillator apparatus, comprising:
the crystal oscillator circuit of claim 8; and
the crystal unit.

10. A control signal generating method, comprising:
generating, in response to a detected ambient temperature, a Bezier curve as a control signal for an oscillating circuit that vibrates a crystal unit.

11. A curve-fitting method, comprising:
utilizing a Bezier curve to approximate, in response to a detected ambient temperature, a control signal for an oscillating circuit that vibrates a crystal unit.
